(19) United States
(12) Patent Application Publication
(10) Pub. No.: US 2026/0305334 A1
(43) Pub. Date: Oct. 1, 2026

(54) SEMICONDUCTOR DEVICE

(71) Applicant: FUJI ELECTRIC CO., LTD., Kawasaki-shi (JP)

(72) Inventor: Shinji TADA, Matsumoto-city (JP)

(73) Assignee: FUJI ELECTRIC CO., LTD., Kawasaki-shi (JP)

(21) Appl. No.: 19/569,730

(22) Filed: Mar. 17, 2026

Related U.S. Application Data
(63) Continuation of application No. PCT/JP2025/002369, filed on Jan. 27, 2025.

(30) Foreign Application Priority Data
Mar. 15, 2024 (JP) 2024-041116

(51) Int. Cl. H10W 40/20; H10D 80/20; H10W 40/00; H10W 40/25; H10W 70/40; H10W 72/30; H10W 90/00

(52) U.S. Cl. CPC H10W 40/235; H10W 40/237; H10W 40/242; H10W 70/481; H10W 72/365; H10W 90/736; H10D 80/231; H10D 80/251; H10W 40/03; H10W 40/251; H10W 72/354

(57) ABSTRACT

Provided is a semiconductor device that can suppress warpage of a semiconductor module. The semiconductor device includes a semiconductor module including a heat dissipation plate, an electrically-conductive plate bonded to a top surface of the heat dissipation plate by a first resin sheet, and a semiconductor chip bonded to a top surface of the electrically-conductive plate by a bonding material. A cooler is bonded to a bottom surface of the semiconductor module by a second resin sheet. A resin sheet having higher electrical insulation than the second resin sheet is used as the first resin sheet. A resin sheet having higher thermal conductivity than the first resin sheet is used as the second resin sheet.

### CROSS-REFERENCE TO RELATED APPLICATION

This application is a Continuation of PCT Application No. PCT/JP2025/002369, filed on Jan. 27, 2025, and claims the priority of Japanese Patent Application No. 2024-041116, filed on Mar. 15, 2024, the content of which are incorporated herein by reference.

### TECHNICAL FIELD

This disclosure relates to a semiconductor device.

### BACKGROUND ART

In the related art, there has been known a semiconductor device including: a semiconductor module including a Cu base, an insulating circuit board placed on the Cu base, and a semiconductor chip placed on the insulating circuit board; and a cooler placed under the Cu base. Generally, such a semiconductor device has a configuration in which the Cu base is bonded to the insulating circuit board via a bonding material (e.g., solder), the insulating circuit board is bonded to the semiconductor chip via a bonding material, and a compound is placed between the Cu base and the cooler.

JP2022-057425A discloses a configuration in which a second heat spreader, an insulating heat dissipation sheet, a first heat spreader, a step absorber, a power semiconductor, and an electrode are placed in this order. JP2022-057425A also discloses a configuration in which a high-performance heat dissipation sheet, graphite, or the like having an adhesive property and a heat dissipation property is used as the step absorber. JP2023-118508A discloses a configuration in which a Cu base plate, a heat dissipation sheet, a Cu pattern section, and a power semiconductor chip are placed in this order. JP2011-116913A discloses a configuration in which a power semiconductor element is placed on the top side of a lead frame, a cooler is placed on the bottom side of the lead frame, and a thermally-conductive resin sheet is placed between the lead frame and the cooler. JP2024-03877A describes a resin case having a roughened adhesive surface as an adhesive surface in contact with an adhesive layer.

### SUMMARY OF INVENTION

### Technical Problem

However, in the configuration using the bonding materials to bond the Cu base to the insulating circuit board and to bond the insulating circuit board to the semiconductor chip, the number of heating steps to melt the bonding material increases, which may cause the semiconductor module to warp by heat. As the semiconductor module warps, a gap is formed between the semiconductor module and the cooler, which causes a possibility that the heat dissipation property may deteriorate. When the semiconductor module is pressed against the cooler to reduce the gap, a stress is applied to the semiconductor module, which causes a possibility that the semiconductor module may break (malfunction). When such a gap is formed, it is necessary to thicken the compound to eliminate the gap.

An object of this disclosure is to provide a semiconductor device that can suppress warpage of a semiconductor module.

### Solution to Problem

In order to achieve the above object, a semiconductor device according to one aspect of this disclosure includes: a semiconductor module including a heat dissipation plate, an electrically-conductive plate bonded to a top surface of the heat dissipation plate by a first resin sheet, and a semiconductor chip bonded to a top surface of the electrically-conductive plate by a bonding material; and a cooler bonded to a bottom surface of the semiconductor module by a second resin sheet. The first resin sheet has higher electrical insulation than the second resin sheet, and the second resin sheet has higher thermal conductivity than the first resin sheet.

The first resin sheet and the second resin sheet may be sheets each obtained by curing a thermosetting resin containing an inorganic filler; and the first resin sheet and the second resin sheet may cure at temperatures lower than a melting point of the bonding material.

The semiconductor module may include a sealing resin sealing the heat dissipation plate, the first resin sheet, the electrically-conductive plate, the bonding material, and the semiconductor chip, and the first resin sheet may cure at a temperature equal to or lower than a temperature at which the sealing resin cures.

The semiconductor module may include a sealing resin sealing the heat dissipation plate, the first resin sheet, the electrically-conductive plate, the bonding material, and the semiconductor chip. The first resin sheet may cover a whole top surface of the heat dissipation plate. The electrically-conductive plate may overlap a portion of a top surface of the first resin sheet which portion excludes an outer edge of the top surface. The top surface of the first resin sheet may have a region around a contact region in contact with the electrically-conductive plate which region has a groove formed to surround the contact region and extending from the top surface of the first resin sheet to reach inside of the heat dissipation plate. The sealing resin may be filled inside the groove.

The semiconductor module may include a sealing resin sealing the heat dissipation plate, the first resin sheet, the electrically-conductive plate, the bonding material, and the semiconductor chip. The first resin sheet may cover a whole top surface of the heat dissipation plate except an outer edge of the top surface. The top surface of the heat dissipation plate may have a region around a contact region in contact with the first resin sheet which region has a groove formed to surround the contact region and extending from the top surface of the heat dissipation plate to reach inside of the heat dissipation plate. The sealing resin may be filled inside the groove.

The semiconductor module may include a sealing resin sealing the heat dissipation plate, the first resin sheet, the electrically-conductive plate, the bonding material, and the semiconductor chip. The semiconductor module may have a bottom surface as a recessed-projecting surface subjected to roughening.

The cooler may have a top surface as a recessed-projecting surface subjected to roughening.

Note that the summary of the invention does not describe all necessary features of the present invention. Subcombinations of these features can also be included in the invention.

### BRIEF DESCRIPTION OF DRAWINGS

FIG. 1 is a view illustrating a sectional configuration of a semiconductor device according to an embodiment;

FIG. 2 is a view illustrating the top surface of a semiconductor module viewed along a line A-A in FIG. 1;

FIG. 3 is a view illustrating an interface between the semiconductor module and a second resin sheet in an area B in FIG. 1 in an enlarged manner;

FIG. 4 is a view illustrating an interface between a cooler and the second resin sheet in an area C in FIG. 1 in an enlarged manner;

FIG. 5 is a flowchart illustrating a manufacturing method of the semiconductor device according to the embodiment;

FIG. 6 is a view illustrating a sectional configuration of a semiconductor device according to a comparative example;

FIG. 7 is a flowchart illustrating a manufacturing method of the semiconductor device according to the comparative example;

FIG. 8 is a view illustrating a sectional configuration of a semiconductor device according to Modification (1);

FIG. 9 is a flowchart illustrating a manufacturing method of the semiconductor device according to Modification (1);

FIG. 10 is a view illustrating a sectional configuration of a semiconductor device according to Modification (2); and

FIG. 11 is a view illustrating the top surface of a semiconductor module viewed along a line D-D in FIG. 10.

### DESCRIPTION OF EMBODIMENTS

The inventor of this disclosure has found the following problem in the course of repeated examination of the aforementioned semiconductor device including: the semiconductor module including the Cu base, the insulating circuit board placed on the Cu base, and the semiconductor chip placed on the insulating circuit board; and the cooler placed under the Cu base. Note that bonding materials are used to bond the Cu base to the insulating circuit board and to bond the insulating circuit board to the semiconductor chip, and a compound is placed between the Cu base and the cooler. At first, the inventor of this disclosure considered a configuration in which, in order to reduce the number of heating steps to melt the bonding materials, the combination of an insulating layer of the insulating circuit board (a DCB substrate), the Cu base, and the bonding material, and the compound are replaced with similar resin sheets having electrical insulation and thermal conductivity. In a case where it is assumed, for example, that such a configuration is applied to a semiconductor element (a power semiconductor element, or the like) dealing with a high voltage and having a high calorific value, the resin sheets are required to have high electrical insulation and high thermal conductivity. However, there is no resin sheet having both high electrical insulation and high thermal conductivity, and it is difficult to achieve the above configuration.

Note that, in this disclosure, “electrical insulation and thermal conductivity of a resin sheet” indicate electrical insulation and thermal conductivity of the resin sheet in its thickness direction. That is, in the following description, “electrical insulation and thermal conductivity of a first resin sheet 7” indicate electrical insulation of the first resin sheet 7 in its thickness direction and thermal conductivity thereof in the thickness direction, and “electrical insulation and thermal conductivity of a second resin sheet 12” indicate electrical insulation of the second resin sheet 12 in its thickness direction and thermal conductivity thereof in the thickness direction.

The following describes an example of a semiconductor device and a manufacturing method thereof according to an embodiment of this disclosure with reference to the drawings. In the description for the drawings, identical or similar constituents have identical or similar reference signs, and redundant descriptions are omitted. Note that the drawings are schematic, and the relationship between thickness and flat dimension, the ratio between layer thicknesses, and the like are different from actual ones. In addition, different drawings may include respective portions having different dimensional relationships or ratios from each other. Besides, the embodiment described below describes devices or methods to embody the technical idea of this disclosure, and the technical idea of this disclosure does not limit a material, a shape, a structure, and the like of a constituent component to those described below.

The definitions of directions such as “up,” “down,” “right,” and “left” in the following description are merely definitions for convenience of the description and do not restrict the technical idea of this disclosure. For example, when a target is rotated by 90° and observed, the “up-down direction” is replaced with the “right-left direction,” and when the target is rotated by 180° and observed, the top and bottom are upside down. The embodiment of this disclosure will be described in the following sequential orders.
1. Overall Configuration of Semiconductor Device
2. Manufacturing Method of Semiconductor Device
3. Operations and Effects
4. Modifications

### 1. Overall Configuration of Semiconductor Device

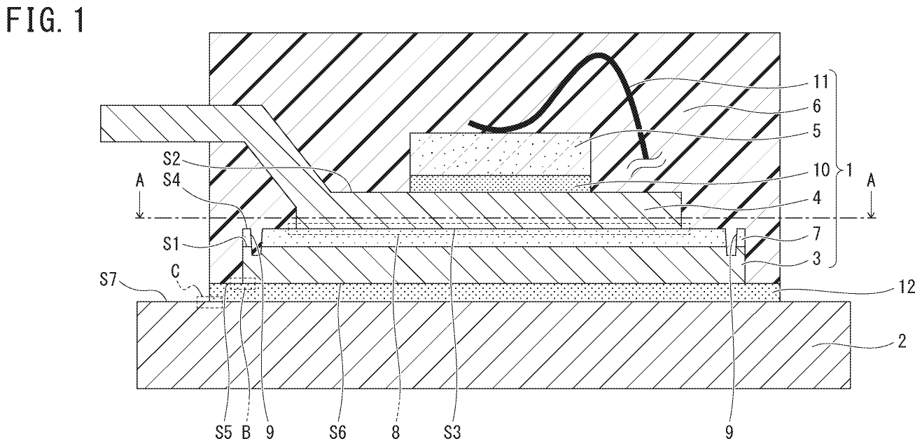

FIG. 1 is a view illustrating a sectional configuration of a semiconductor device according to the present embodiment. As illustrated in FIG. 1, the semiconductor device according to the present embodiment includes a semiconductor module 1 and a cooler 2.

The semiconductor module 1 is a power semiconductor module including a power semiconductor element (hereinafter also referred to as a “semiconductor chip”), which is a semiconductor element for electric power. For example, the semiconductor module 1 can control the rotation speed, acceleration, or the like of a motor connected to an inverter (not illustrated). The semiconductor module 1 includes a heat dissipation plate 3, an electrically-conductive plate 4 placed on a top surface S1 of the heat dissipation plate 3, a semiconductor chip 5 placed on a top surface S2 of the electrically-conductive plate 4, and a sealing resin 6 sealing these members.

The heat dissipation plate 3 is formed in a rectangular shape larger than the electrically-conductive plate 4 in a plan view to cover a whole bottom surface S3 (a surface facing the cooler 2) of the electrically-conductive plate 4. The heat dissipation plate 3 may have corners chamfered into an R-shape or a C-shape. The heat dissipation plate 3 is mainly made of metal having excellent thermal conductivity. The metal usable herein may be, for example, copper (Cu), aluminum (Al), and alloys containing either of them. The heat dissipation plate 3 may have a thickness of 0.1 mm or more and 2.5 mm or less, for example.

The electrically-conductive plate 4 is bonded to the top surface S1 of the heat dissipation plate 3 by a first resin sheet 7 having electrical insulation and thermal conductivity. That is, the first resin sheet 7 has a bottom surface in contact with the heat dissipation plate 3 and a top surface S4 in contact with the electrically-conductive plate 4, so that the first resin sheet 7 functions as an adhesive layer for bonding (in other words, joining) the heat dissipation plate 3 to the electrically-conductive plate 4. The first resin sheet 7 is formed in the same shape as the top surface S1 in a plan view to cover the whole top surface S1 of the heat dissipation plate 3. As the first resin sheet 7, a resin sheet having higher electrical insulation than a second resin sheet 12 (described later) is used. That is, the first resin sheet 7 has a breakdown voltage [kV] larger than the breakdown voltage [kV] of the second resin sheet 12. As the electrical insulation of the first resin sheet 7 is enhanced, the electrically-conductive plate 4 and the heat dissipation plate 3 can be electrically insulated from each other by the first resin sheet 7, thereby making it possible to prevent the electrically-conductive plate 4 from being electrically connected to the heat dissipation plate 3. The breakdown voltage of the first resin sheet 7 may be, for example, 4 kV/100 μm or more. The thermal conductivity of the first resin sheet 7 may be, for example, 3.6 W/mK or more.

As the first resin sheet 7, a sheet in which a thermosetting resin composition containing an inorganic filler excellent in electrical insulation and thermal conductivity is cured on a thermosetting resin (matrix resin) is usable, for example. In a case where such a sheet is used, the heat dissipation plate 3 and the electrically-conductive plate 4 can be bonded (joined) by the first resin sheet 7, for example, in such a manner that the first resin sheet 7 with a semi-cured thermosetting resin (matrix resin) is placed between the heat dissipation plate 3 and the electrically-conductive plate 4 and then subjected to pressurization and heating so as to cure the first resin sheet 7 completely with the first resin sheet 7 in contact with the heat dissipation plate 3 and the electrically-conductive plate 4. The thermosetting resins usable herein may be, for example, epoxy resin, liquid crystal polymer (LCP resin), heat-curable urethane resin, silicon resin, or polyimide resin. The inorganic filler usable herein may be, for example, boron nitride (BN), aluminum oxide (Al₂O₃), or aluminum nitride (AlN). As an example of the first resin sheet 7, the combination of epoxy resin and boron nitride (BN), the combination of liquid crystalline polymer, boron nitride, and aluminum oxide, the combination of urethane resin and boron nitride, and the combination of silicon resin and aluminum nitride can be used.

In a case where a sheet obtained by curing a thermosetting resin composition (thermosetting resin+inorganic filler) as described above is used, the temperature (in other words, the curing temperature) at which the first resin sheet 7 cures is adjusted to be lower than the melting point (for example, around 220° C.) of the bonding material 10. Hereby, the temperature out of curing conditions (pressure and temperature) of the first resin sheet 7 can be lowered, so that heat applied to the semiconductor module 1 can be reduced in a step of completely curing the semi-cured first resin sheet 7. More preferably, the temperature (in other words, the curing temperature) at which the first resin sheet 7 cures is adjusted to be lower than the melting point of the bonding material 10 and to be equal to or lower than the temperature at which the sealing resin 6 cures (the melting point of the bonding material 10>the temperature at which the sealing resin 6 cures≥the curing temperature of the first resin sheet 7). Hereby, the semi-cured first resin sheet 7 can be completely cured by pressurization and heating for resin sealing to be performed in a resin sealing step, thereby making it possible to reduce the number of heating steps to be performed in a manufacturing process. As a method for adjusting the temperature at which the first resin sheet 7 cures, the amounts of addition of the inorganic filler and various additives may be adjusted, for example. The temperature at which the first resin sheet 7 cures may be approximately 120° C. or higher and 180° C. or lower, for example.

As the thickness of the first resin sheet 7 is thicker, the electrical insulation improves. However, the thermal conductivity of the first resin sheet 7 decreases, so that heat is accumulated in the semiconductor chip 5. In the meantime, as the thickness of the first resin sheet 7 is thinner, the thermal conductivity of the first resin sheet 7 improves. However, the electrical insulation of the first resin sheet 7 decreases, so that a possibility that the electrically-conductive plate 4 may be electrically connected to the heat dissipation plate 3 increases. Therefore, it is preferable that the thickness of the first resin sheet 7 be set within a number range in which the lower limit is a thickness that can achieve a breakdown voltage without dielectric breakdown for the operating voltage of the semiconductor module 1, and the upper limit is a thickness that can achieve thermal conductivity at the same level as that of the bonding material 10 (solder). For example, the thickness of the first resin sheet 7 may be 50 μm or more and 500 μm or less.

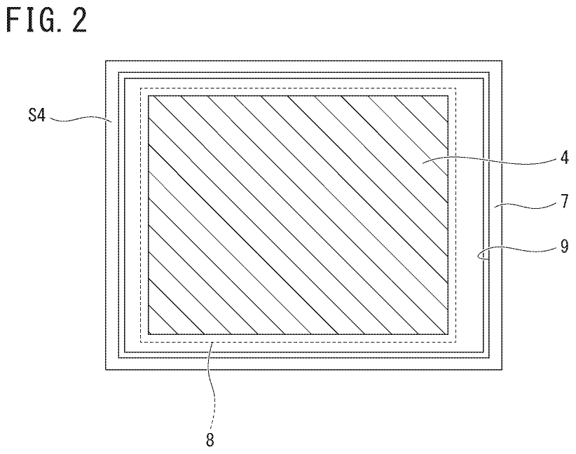

As illustrated in FIG. 2, on the top surface S4 of the first resin sheet 7, a region around a contact region (hereinafter also referred to as a “first contact region 8”) in contact with the electrically-conductive plate 4 has a groove 9 extending from the top surface S4 of the first resin sheet 7 to reach the inside of the heat dissipation plate 3. FIG. 2 is a view illustrating the top surface of the semiconductor module 1 viewed along a line A-A in FIG. 1. In FIG. 2, the sealing resin 6, the second resin sheet 12, and the cooler 2 are not illustrated. FIG. 2 also illustrates a case where the groove 9 is formed in a region around the first contact region 8 to surround the first contact region 8. The sealing resin 6 enters the inside of the groove 9 through the opening of the groove 9 so that the sealing resin 6 is filled in the groove 9. Since the sealing resin 6 is filled in the groove 9, even if water enters, from outside (an outer edge portion), a structure (the heat dissipation plate 3, the first resin sheet 7, the electrically-conductive plate 4, the bonding material 10, and the semiconductor chip 5) sealed with the sealing resin 6, the sealing resin 6 in the groove 9 can prevent the water thus entering, thereby making it possible to prevent the water from entering between the first resin sheet 7 and each of the electrically-conductive plate 4 and the heat dissipation plate 3.

Here, for example, in a case where a thermosetting resin composition containing boron nitride (BN) is used as the first resin sheet 7, if the first resin sheet 7 makes contact with water, the electrical insulation of the first resin sheet 7 decreases. Accordingly, when water is prevented from entering between the first resin sheet 7 and each of the electrically-conductive plate 4 and the heat dissipation plate 3, it is possible to more surely prevent the electrically-conductive plate 4 from being electrically connected to the heat dissipation plate 3. As a method for forming the groove 9, the heat dissipation plate 3 is bonded to the electrically-conductive plate 4 by the first resin sheet 7, and then laser machining is performed by applying a laser beam to the top surface S4 of the first resin sheet 7, for example.

The electrically-conductive plate 4 is formed in a rectangular shape smaller than the first resin sheet 7 (the heat dissipation plate 3) in a plan view to overlap a portion (a central portion) of the top surface S4 of the first resin sheet 7 which portion excludes the outer edge of the top surface S4. The electrically-conductive plate 4 functions as a circuit board forming a circuit pattern. FIG. 1 illustrates a case where the semiconductor device of this disclosure is applied to a configuration (a lead-frame type) including a lead frame, and a die pad (that is, a metal plate) of the lead frame is used as the electrically-conductive plate 4. Similarly to the heat dissipation plate 3, the electrically-conductive plate 4 is mainly made of metal having excellent electrical conductivity. The metal usable herein may be, for example, copper (Cu), aluminum (Al), or alloys containing either of them. The electrically-conductive plate 4 may have a thickness of 0.1 mm or more and 2.0 mm or less, for example.

The semiconductor chip 5 is bonded to the top surface S2 of the electrically-conductive plate 4 by the bonding material 10. As the bonding material 10, solder or a sintered material (copper, silver, and the like) can be used, for example. The present embodiment deals with a case where the semiconductor chip 5 is constituted by an insulated gate bipolar transistor (IGBT). Note that the semiconductor chip 5 may be constituted by a metal oxide semiconductor field effect transistor (MOSFET), an electrostatic induction (SI) thyristor, a gate turn-off (GTO) thyristor, a diode, or the like, for example. The semiconductor chip 5 is constituted by a semiconductor substrate made of silicon (Si), silicon carbide (SiC), gallium nitride (GaN), gallium oxide (Ga₂O₃), or the like, for example. The semiconductor chip 5 includes a collector electrode (not illustrated) placed on the bottom surface side, and an emitter electrode (not illustrated) and a gate electrode (not illustrated) placed on the top surface side. The collector electrode of the semiconductor chip 5 is bonded to the top surface S2 of the electrically-conductive plate 4 by the bonding material 10. The emitter electrode of the semiconductor chip 5 is bonded to a bonding wire 11. A control terminal (not illustrated) is electrically connected to the gate electrode of the semiconductor chip 5 via a bonding wire or the like (not illustrated). In response to the gate electrode of the semiconductor chip 5 receiving an ON-OFF electrical signal, current flowing between the collector electrode and the emitter electrode of the semiconductor chip 5 is controlled to be ON or OFF.

The sealing resin 6 is formed in a rectangular-solid shape to seal the heat dissipation plate 3, the first resin sheet 7, the electrically-conductive plate 4, the bonding material 10, the semiconductor chip 5, and so on. The sealing resin 6 has a bottom surface S5 formed to be flush with a bottom surface S6 of the heat dissipation plate 3 so that the bottom surface S6 of the heat dissipation plate 3 is exposed. As the sealing resin 6, epoxy, silicon, urethane, polyimide, and polyamide can be used, for example. Particularly, epoxy resin mixed with a filler is preferable. The sealing resin 6 enters the inside of the groove 9 formed on the top surface S4 of the first resin sheet 7 to be filled in the groove 9.

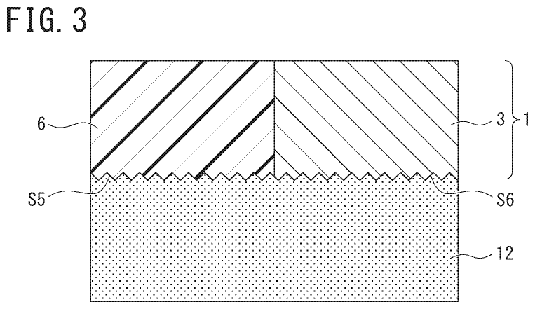

As illustrated in FIG. 3, the bottom surface of the semiconductor module 1 (including the bottom surface S5 of the sealing resin 6 and the bottom surface S6 of the heat dissipation plate 3) is a recessed-projecting surface subjected to roughening. FIG. 3 is a view illustrating an interface between the semiconductor module 1 and the second resin sheet 12 in an area B in FIG. 1 in an enlarged manner. Due to the recessed-projecting surface, the second resin sheet 12 enters recesses and projections on the recessed-projecting surface to achieve an anchor effect, thereby making it possible to improve the adhesion strength of the second resin sheet 12. This makes it possible to prevent water from entering between the semiconductor module 1 and the second resin sheet 12 from outside. Here, due to repetition of the heat cycle of operation and stop of the semiconductor device, the sealing resin 6 repeatedly expands and contracts, which may cause cracking from the outer edge side to the inside on the interface between the semiconductor module 1 and the second resin sheet 12. In this regard, as described above, due to the improvement of the adhesion strength of the second resin sheet 12, it is possible to suppress the progress of cracking of the interface between the semiconductor module 1 and the second resin sheet 12.

The recessed-projecting surface may have an arithmetic average roughness Ra of 1 μm or more and 10 μm or less, for example. The arithmetic average roughness Ra may be preferably 2 μm or more and 5 μm or less, for example. When the arithmetic average roughness Ra is too large, some recesses may not be filled with the second resin sheet 12, which causes a possibility that the adhesion strength of the second resin sheet 12 may deteriorate. In the meantime, if the arithmetic average roughness Ra is too small, the anchor effect may not be obtained, which causes a possibility that the adhesion strength of the second resin sheet 12 may deteriorate. Note that the arithmetic average roughness Ra can be measured by a laser microscope, an atomic force microscope, and the like. The roughening can be performed by laser machining, polishing, blasting, cutting, or etching, for example.

The cooler 2 is bonded to the bottom surface of the semiconductor module 1 (including the bottom surface S5 of the sealing resin 6 and the bottom surface S6 of the heat dissipation plate 3) via the second resin sheet 12 having thermal conductivity. That is, the second resin sheet 12 has a bottom surface in contact with the cooler 2 and a top surface in contact with the semiconductor module 1, so that the second resin sheet 12 functions as an adhesive layer for bonding (joining) the cooler 2 to the semiconductor module 1. The second resin sheet 12 is formed in the same shape as the bottom surface of the semiconductor module 1 in a plan view to cover the whole bottom surface of the semiconductor module 1. As the second resin sheet 12, a resin sheet having higher thermal conductivity than the first resin sheet 7 is used. That is, the second resin sheet 12 has a thermal resistance [K/W] smaller than the thermal resistance [K/W] of the first resin sheet 7. Alternatively, the second resin sheet 12 has a thermal conductivity [W/mK] larger than the thermal conductivity [W/mK] of the first resin sheet 7. As the thermal conductivity of the second resin sheet 12 is enhanced, thermal conduction from the semiconductor module 1 to the cooler 2 can be improved, thereby making it possible to more efficiently dissipate heat generated by the semiconductor module 1. The thermal conductivity of the second resin sheet 12 may be, for example, 7 W/mK or more and 800 W/mK or less. Note that the second resin sheet 12 may be a resin sheet (a resin sheet excellent in electrical conductivity) without electrical insulation.

As the second resin sheet 12, a sheet in which a thermosetting resin composition containing an inorganic filler excellent in thermal conductivity is cured on a thermosetting resin (matrix resin) is usable, for example. In a case where such a sheet is used, the cooler 2 and the semiconductor module 1 can be bonded (joined) by the second resin sheet 12, for example, in such a manner that the second resin sheet 12 with a semi-cured thermosetting resin (matrix resin) is placed between the cooler 2 and the semiconductor module 1 and then subjected to pressurization and heating so as to cure the second resin sheet 12 completely with the second resin sheet 12 in contact with the cooler 2 and the semiconductor module 1. The thermosetting resin may be, for example, urethane or epoxy resin. The inorganic filler may be, for example, black-lead, graphite, carbon nanotube, carbon fiber, silver (Ag), or aluminum (Al). As an example of the second resin sheet 12, the combination of urethane and black-lead can be used. In a case where a sheet obtained by curing a thermosetting resin composition (thermosetting resin+inorganic filler) as described above is used, the temperature (curing temperature) at which the second resin sheet 12 cures is adjusted to be lower than the melting point of the bonding material 10. Hereby, the temperature as the curing conditions of the second resin sheet 12 can be reduced, so that heat applied to the semiconductor module 1 can be reduced in a step of completely curing the semi-cured second resin sheet 12. The temperature at which the second resin sheet 12 cures may be approximately 90° C. or more and 180° C. or less, for example.

As the thickness of the second resin sheet 12 is thinner, the thermal conductivity of the second resin sheet 12 improves. However, if the second resin sheet 12 is too thin, a gap is formed between the semiconductor module 1 and the cooler 2, so that thermal conductivity from the semiconductor module 1 to the cooler 2 decreases. Therefore, it is preferable that the thickness of the second resin sheet 12 be set within a number range in which the lower limit is a thickness that can eliminate the gap between the semiconductor module 1 and the cooler 2, and the upper limit is a thickness that can achieve thermal conductivity at the same level as that of the bonding material 10 (solder). For example, the thickness of the second resin sheet 12 may be 100 μm or more and 500 μm or less.

The cooler 2 has a top surface S7, which is a generally flat cooling surface that exchanges heat with the semiconductor module 1 by the second resin sheet 12. The cooling surface (the top surface S7) is formed in a rectangular shape larger than the bottom surface S6 in a plan view to cover the whole bottom surface S6 of the heat dissipation plate 3. The cooler 2 cools the bottom surface of the semiconductor module 1 (the bottom surface S6 of the heat dissipation plate 3), so that heat generated by the semiconductor chip 5 (that is, heat accumulated in the semiconductor module 1) dissipates. As the cooler 2, a cooler through which a refrigerant circulates, or a heat sink including a plurality of fins for heat dissipation can be used.

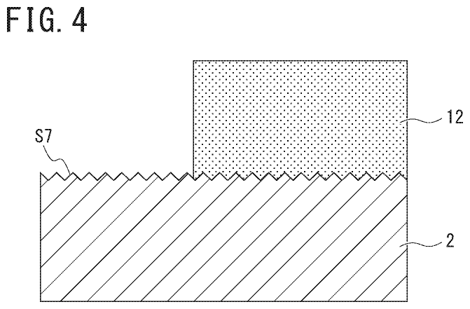

As illustrated in FIG. 4, the top surface S7 of the cooler 2 is a recessed-projecting surface subjected to roughening. FIG. 4 is a view illustrating an interface between the cooler 2 and the second resin sheet 12 in an area C in FIG. 1 in an enlarged manner. Due to the recessed-projecting surface, the second resin sheet 12 enters recesses and projections on the recessed-projecting surface to achieve an anchor effect, thereby making it possible to improve the adhesion strength of the second resin sheet 12. Here, due to repetition of the heat cycle of operation and stop of the semiconductor device, the sealing resin 6 repeatedly expands and contracts, which may cause cracking from the outer edge side to the inside on the interface between the second resin sheet 12 and the cooler 2. In this regard, as described above, due to the improvement of the adhesion strength of the second resin sheet 12, it is possible to suppress the progress of cracking of the interface between the second resin sheet 12 and the cooler 2.

The recessed-projecting surface may have an arithmetic average roughness Ra of 1 μm or more and 10 μm or less, for example. The arithmetic average roughness Ra may be preferably 2 μm or more and 5 μm or less, for example. When the arithmetic average roughness Ra is too large, some recesses may not be filled with the second resin sheet 12, which causes a possibility that the adhesion strength of the second resin sheet 12 may deteriorate. In the meantime, when the arithmetic average roughness Ra is too small, the anchor effect may not be obtained, which causes a possibility that the adhesion strength of the second resin sheet 12 may deteriorate. Note that the arithmetic average roughness Ra can be measured by a laser microscope, an atomic force microscope, and the like. The roughening can be performed by laser machining, polishing, blasting, cutting, or etching, for example.

### 2. Manufacturing Method of Semiconductor Device

Next will be described an example of a manufacturing method for manufacturing the semiconductor device according to the present embodiment, with reference to the drawings.

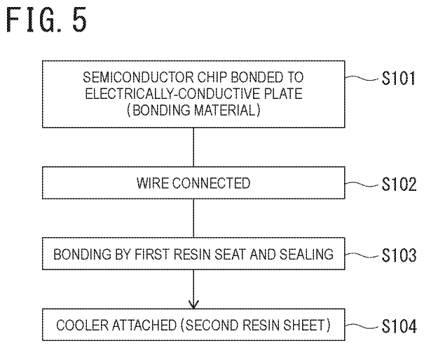

FIG. 5 is a flowchart illustrating the manufacturing method of the semiconductor device according to the present embodiment.

First, the bonding material 10 and the semiconductor chip 5 are placed in this order on the top surface S2 of the electrically-conductive plate 4 (in FIG. 1, the die pad of the lead frame) (step S101 in FIG. 5). Subsequently, the entirety of the electrically-conductive plate 4, the bonding material 10, and the semiconductor chip 5 is heated to melt the bonding material 10, so that the electrically-conductive plate 4 is bonded to the semiconductor chip 5 by the bonding material 10 (step S101 in FIG. 5). Subsequently, the bonding wire 11 is connected to the semiconductor chip 5 (step S102 in FIG. 5). Subsequently, the bottom surface S3 of the electrically-conductive plate 4 is temporarily joined to the top surface S1 of the heat dissipation plate 3 by the semi-cured first resin sheet 7 (step S103 in FIG. 5). Subsequently, a laser beam is applied to the top surface S4 of the first resin sheet 7 to form the groove 9 (step S103 in FIG. 5).

Subsequently, the heat dissipation plate 3, the first resin sheet 7, the electrically-conductive plate 4, and the semiconductor chip 5 are placed in a metal mold (not illustrated) for resin sealing, and the sealing resin 6 is introduced into the metal mold to perform resin sealing (step S103 in FIG. 5). At this time, the semi-cured first resin sheet 7 is completely cured by pressurization and heating for resin sealing, so that the first resin sheet 7 closely adheres to the heat dissipation plate 3 and the electrically-conductive plate 4, and the heat dissipation plate 3 is bonded (joined) to the electrically-conductive plate 4. For example, due to the pressurization and heating for resin sealing, performed in the resin sealing step, pressure and temperature are adjusted to satisfy both the curing conditions of the sealing resin 6 and the curing conditions of the first resin sheet 7 (for example, around 200° C.), so that the heat dissipation plate 3 is bonded (joined) to the electrically-conductive plate 4 by the first resin sheet 7. Hereby, the semiconductor module 1 is formed.

Subsequently, the bottom surface of the semiconductor module 1 (including the bottom surface S5 of the sealing resin 6 and the bottom surface S6 of the heat dissipation plate 3) and the top surface S7 of the cooler 2 are subjected to roughening to form recessed-projecting surfaces (S104 in FIG. 5). Subsequently, the bottom surface of the semiconductor module 1 is attached to the top surface S7 of the cooler 2 by the second resin sheet 12 (step S104 in FIG. 5). For example, due to the pressurization and heating, the pressure and temperature are adjusted to satisfy the curing conditions of the second resin sheet 12 (for example, around 200° C.), so that the cooler 2 is bonded (joined) to the semiconductor module 1 by the second resin sheet 12.

As a result, the semiconductor device according to the present embodiment illustrated in FIG. 1 is completed.

### 3. Operations and Effects

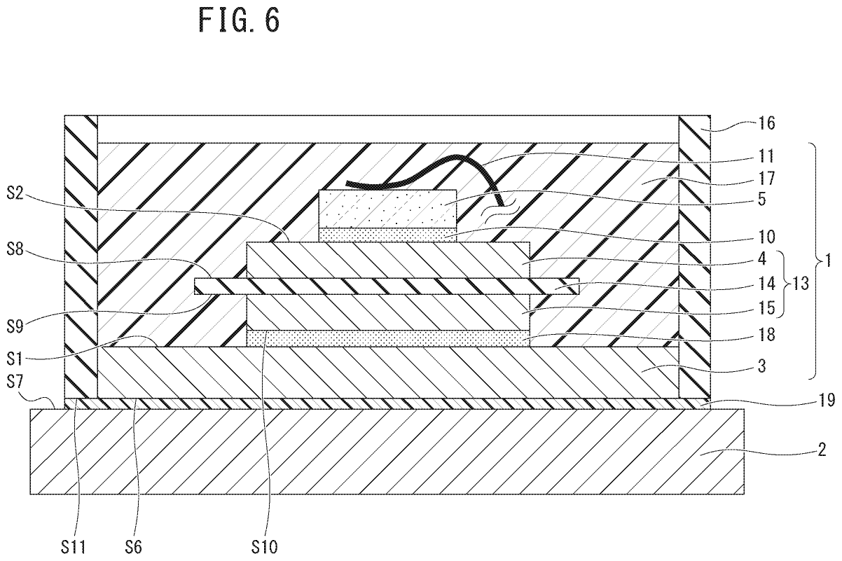

Herein, with reference to FIG. 6, a semiconductor device according to a comparative example will be described. As illustrated in FIG. 6, the semiconductor device according to the comparative example is different from the semiconductor device according to the present embodiment illustrated in FIG. 1 in that the semiconductor module 1 has a configuration in which an insulating circuit board 13 and the semiconductor chip 5 are stacked in this order on the top surface S1 of the heat dissipation plate 3. As the insulating circuit board 13, a direct copper bonding substrate (a DCB substrate) can be used, for example. The insulating circuit board 13 includes an insulating layer 14 (for example, ceramic), the electrically-conductive plate 4 placed on a top surface S8 of the insulating layer 14, and a cooling plate 15 (for example, a metal plate) placed on a bottom surface S9 of the insulating layer 14. The semiconductor device according to the comparative example also includes a case 16 configured to store the semiconductor module 1, and a silicone gel 17 configured to seal the semiconductor module 1 instead of the sealing resin 6. The heat dissipation plate 3 is bonded to the insulating circuit board 13 by a bonding material 18, the insulating circuit board 13 is bonded to the semiconductor chip 5 by the bonding material 10, and a compound 19 is placed between the heat dissipation plate 3 and the cooler 2.

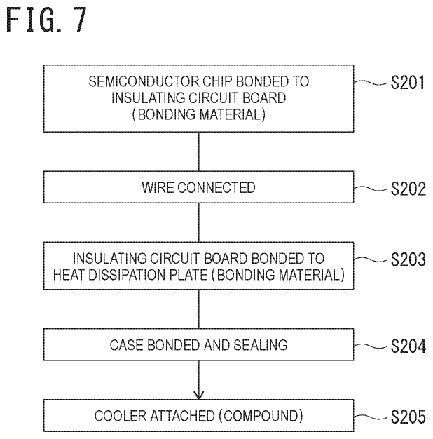

At the time when the semiconductor device according to the comparative example is manufactured, the bonding material 10 and the semiconductor chip 5 are first placed in this order on the top surface S2 of the insulating circuit board 13 (the electrically-conductive plate 4) (step S201 in FIG. 7). Subsequently, the entirety of the insulating circuit board 13, the bonding material 10, and the semiconductor chip 5 is heated to melt the bonding material 10, so that the insulating circuit board 13 is bonded to the semiconductor chip 5 by the bonding material 10 (step S201 in FIG. 7). Subsequently, the bonding wire 11 is connected to the semiconductor chip 5 (step S202 in FIG. 7). Subsequently, the bonding material 18 and the insulating circuit board 13 (including the semiconductor chip 5) are placed in this order on the top surface S1 of the heat dissipation plate 3 (step S203 in FIG. 7). Subsequently, the entirety of the heat dissipation plate 3, the bonding material 18, the insulating circuit board 13, and the semiconductor chip 5 is heated to melt the bonding material 18, so that the heat dissipation plate 3 is bonded to the insulating circuit board 13 by the bonding material 18 (step S203 in FIG. 7). Subsequently, the lower end of the case 16 is joined to the heat dissipation plate 3 by an adhesive (not illustrated) (step S204 in FIG. 7). Subsequently, the silicone gel 17 is introduced into the case 16 to seal the heat dissipation plate 3, the insulating circuit board 13, and the semiconductor chip 5 (step S204 in FIG. 7). Hereby, the semiconductor module 1 is formed. Subsequently, the bottom surface of the semiconductor module 1 (including the bottom surface S11 of the case 16 and the bottom surface S6 of the heat dissipation plate 3) is attached to the top surface S7 of the cooler 2 (step S205 in FIG. 7). At this time, the compound 19 is placed in a gap between the semiconductor module 1 and the cooler 2.

As a result, the semiconductor device according to the comparative example illustrated in FIG. 6 is completed.

Due to such a manufacturing procedure, in the semiconductor device according to the comparative example, a heating step (at the first time) to melt the bonding material 10 is performed at the time of bonding the insulating circuit board 13 to the semiconductor chip 5, and a heating step (at the second time) to melt the bonding material 18 is performed at the time of joining the heat dissipation plate 3 to the insulating circuit board 13 by the bonding material 18. Because of this, the number of heating steps increases, which may cause the semiconductor module 1 to warp by heat. Due to the warpage of the semiconductor module 1, a gap is formed between the semiconductor module 1 and the cooler 2, which may cause a possibility that the heat dissipation property may deteriorate. When the semiconductor module 1 is pressed against the cooler 2 to reduce the gap, a stress is applied to the semiconductor module 1, which causes a possibility that the semiconductor module 1 may break (malfunction). When such a gap is formed, it is necessary to thicken the compound 19 to eliminate the gap.

In contrast, in the semiconductor device according to the present embodiment, the semiconductor module 1 includes the heat dissipation plate 3, the electrically-conductive plate 4 bonded to the top surface S1 of the heat dissipation plate 3 by the first resin sheet 7, and the semiconductor chip 5 bonded to the top surface of the electrically-conductive plate 4 by the bonding material 10, as illustrated in FIG. 1. Besides, the cooler 2 is bonded to the bottom surface S6 of the heat dissipation plate 3 by the second resin sheet 12. In addition, a resin sheet having higher electrical insulation than the second resin sheet 12 is used as the first resin sheet 7, and a resin sheet having higher thermal conductivity than the first resin sheet 7 is used as the second resin sheet 12. As the electrical insulation of the first resin sheet 7 is enhanced, the electrically-conductive plate 4 and the heat dissipation plate 3 can be electrically insulated from each other by the first resin sheet 7, and the first resin sheet 7 can prevent the electrically-conductive plate 4 from being electrically connected to the heat dissipation plate 3. Besides, since the thermal conductivity of the second resin sheet 12 is enhanced, thermal conduction from the semiconductor module 1 to the cooler 2 can be performed efficiently.

In the semiconductor device according to the present embodiment, the first resin sheet 7 is used to bond the heat dissipation plate 3 to the electrically-conductive plate 4, and the second resin sheet 12 is used to bond the semiconductor module 1 to the cooler 2. This can reduce the number of heat steps to melt a bonding material, thereby making it possible to suppress warpage of the semiconductor module 1 by heat. As a result, it is possible to suppress a gap from being formed between the semiconductor module 1 and the cooler 2, thereby making it possible to suppress the heat dissipation property from decreasing. Since the gap is suppressed, it is possible to reduce force to press the semiconductor module 1 against the cooler 2, thereby making it possible to prevent breakage (malfunction) of the semiconductor module 1. It is also possible to omit the compound 19 (see FIG. 6) to fill the gap between the semiconductor module 1 and the cooler 2. Note that pressurization and heating are performed to completely cure the semi-cured first resin sheet 7 and the semi-cured second resin sheet 12. However, the temperatures as the curing conditions of the first resin sheet 7 and the second resin sheet 12 are lower than the temperature at the time of the heating step to melt the bonding material, and therefore, the heating does not largely affect the warpage of the semiconductor module 1. Particularly, the first resin sheet 7 is cured by pressurization and heating for resin sealing to be performed in the resin sealing step, thereby making it possible to further suppress the warpage of the semiconductor module 1 by heat.

In other words, the inventor of this disclosure uses resin sheets of different types of (resin sheets having different characteristics) for the first resin sheet 7 and the second resin sheet 12, instead of using resin sheets of the same type. More specifically, a resin sheet having high electrical insulation is used for the first resin sheet 7, and a resin sheet having high thermal conductivity is used for the second resin sheet 12. With the use of resin sheets having different characteristics, high electrical insulation and high thermal conductivity are achieved as a whole. With such a configuration, in the semiconductor device according to the present embodiment, a configuration in which the first resin sheet 7 is used instead of the combination of the insulating layer 14, the cooling plate 15, and the bonding material 18 as illustrated in FIG. 6, and the second resin sheet 12 is used instead of the compound 19 illustrated in FIG. 6 can be achieved, thereby resulting in that the number of heating steps to melt a bonding material (that is, steps that affect the warpage of the semiconductor module 1) can be reduced.

### 4. Modifications

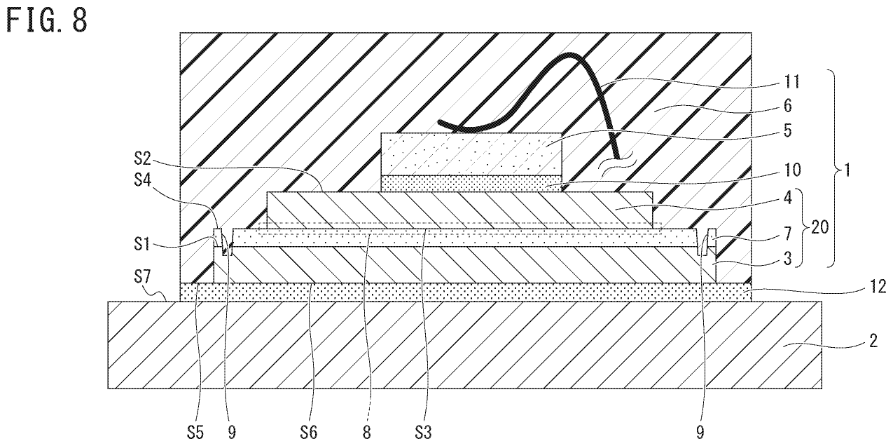

(1) Note that the present embodiment describes an example in which the present invention is applied to a configuration (a lead-frame type) including a lead frame and using a die pad of the lead frame as the electrically-conductive plate 4. However, other configurations may be employed. For example, as illustrated in FIG. 8, the present invention may be applied to a well-known configuration (a substrate type) in which a metal plate including no lead (inner lead, outer lead) is used as the electrically-conductive plate 4, and an insulating circuit board 20 is formed by the heat dissipation plate 3, the first resin sheet 7, and the electrically-conductive plate 4. In the substrate type, a terminal pin (not illustrated) or the like is used as a main terminal for external connection (a P-terminal, an N-terminal, an M-terminal, or the like).

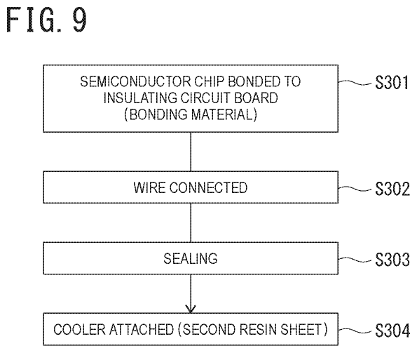

Next will be described an example of a manufacturing method for manufacturing the semiconductor device according to Modification (1). First, the bottom surface S3 of the electrically-conductive plate 4 is bonded (joined) to the top surface S1 of the heat dissipation plate 3 by the first resin sheet 7 to form the insulating circuit board 20 (step S301 in FIG. 9). Subsequently, the bonding material 10 and the semiconductor chip 5 are placed in this order on the top surface S2 of the insulating circuit board 20 (the electrically-conductive plate 4) (step S301 in FIG. 9). Subsequently, the entirety of the insulating circuit board 20, the bonding material 10, and the semiconductor chip 5 is heated to melt the bonding material 10, so that the insulating circuit board 20 is bonded to the semiconductor chip 5 by the bonding material 10 (step S301 in FIG. 9). Subsequently, the bonding wire 11 is connected to the semiconductor chip 5 (step S302 in FIG. 9). Subsequently, a laser beam is applied to the top surface S4 of the first resin sheet 7 to form the groove 9 (step S302 in FIG. 9). Subsequently, the insulating circuit board 20 and the semiconductor chip 5 are placed in a metal mold (not illustrated) for resin sealing, and the sealing resin 6 is introduced into the metal mold to perform resin sealing (step S303 in FIG. 9). Hereby, the semiconductor module 1 is formed.

Subsequently, the bottom surface of the semiconductor module 1 (including the bottom surface S5 of the sealing resin 6 and the bottom surface S6 of the heat dissipation plate 3) and the top surface S7 of the cooler 2 are subjected to roughening to form recessed-projecting surfaces (S304 in FIG. 9). Subsequently, the bottom surface of the semiconductor module 1 (including the bottom surface S5 of the sealing resin 6 and the bottom surface S6 of the heat dissipation plate 3) is attached to the top surface S7 of the cooler 2 by the second resin sheet 12 (step S304 in FIG. 9). As a result, the semiconductor device according to Modification (1) illustrated in FIG. 8 is completed.

Note that, in a case where the present invention is applied to the substrate type, the semiconductor device may include a case for storing the semiconductor module 1. In a case where the semiconductor device includes the case, the resin sealing step as step S303 in FIG. 9 may be a step of introducing a silicone gel into the case after the case is attached.

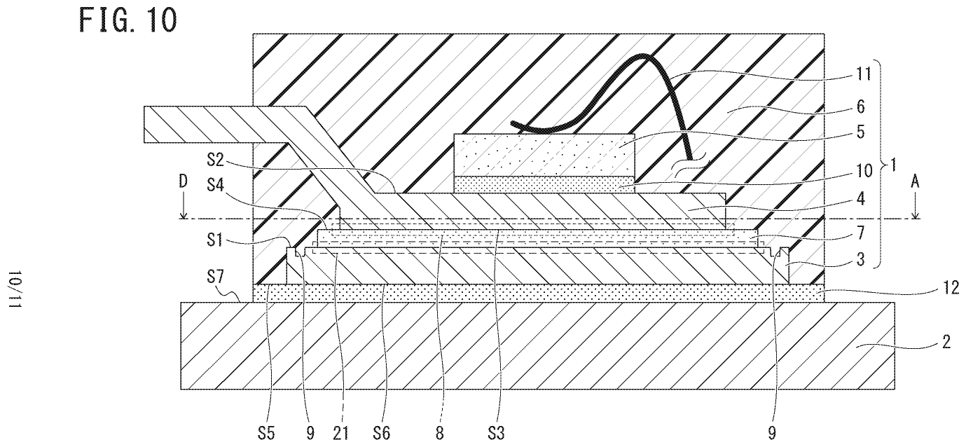

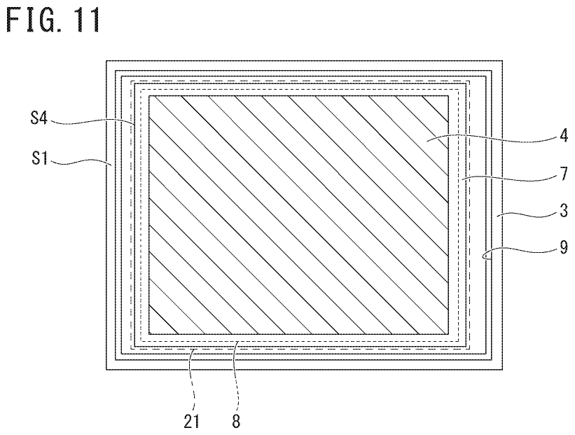

(2) The present embodiment deals with an example in which the groove 9 extending from the top surface S4 of the first resin sheet 7 to reach the inside of the heat dissipation plate 3 is formed on the top surface S4 of the first resin sheet 7. However, other configurations can be employed. For example, as illustrated in FIG. 10 and FIG. 11, in a case where the first resin sheet 7 covers the whole top surface S1 of the heat dissipation plate 3 except the outer edge of the top surface S1, the groove 9 may be formed in a region (that is, a region not covered with the first resin sheet 7) around a contact region (hereinafter also referred to as a “second contact region 21”) in contact with the first resin sheet 7, on the top surface S1 of the heat dissipation plate 3. In this case, the groove 9 is formed to surround the second contact region 21 and to extend from the top surface S1 of the heat dissipation plate 3 to reach the inside of the heat dissipation plate 3. The sealing resin 6 enters the inside of the groove 9 through the opening of the groove 9 so that the sealing resin 6 is filled in the groove 9. Since the sealing resin 6 is filled in the groove 9, even if water enters, from outside (an outer edge portion), a structure (the heat dissipation plate 3, the first resin sheet 7, the electrically-conductive plate 4, the bonding material 10, and the semiconductor chip 5) sealed with the sealing resin 6, the sealing resin 6 in the groove 9 can prevent the water thus entering, thereby making it possible to prevent the water from entering between the first resin sheet 7 and each of the electrically-conductive plate 4 and the heat dissipation plate 3. FIG. 11 is a view illustrating the top surface of the semiconductor module 1 viewed along a line D-D in FIG. 10. In FIG. 11, the sealing resin 6, the second resin sheet 12, and the cooler 2 are not illustrated.

1. A semiconductor device comprising:
a semiconductor module including a heat dissipation plate, an electrically-conductive plate bonded to a top surface of the heat dissipation plate by a first resin sheet, and a semiconductor chip bonded to a top surface of the electrically-conductive plate by a bonding material; and
a cooler bonded to a bottom surface of the semiconductor module by a second resin sheet, wherein:
the first resin sheet has higher electrical insulation than the second resin sheet; and
the second resin sheet has higher thermal conductivity than the first resin sheet.

2. The semiconductor device according to claim 1, wherein:
the first resin sheet and the second resin sheet are sheets each obtained by curing a thermosetting resin containing an inorganic filler; and
the first resin sheet and the second resin sheet cure at temperatures lower than a melting point of the bonding material.

3. The semiconductor device according to claim 2, wherein:
the semiconductor module includes a sealing resin sealing the heat dissipation plate, the first resin sheet, the electrically-conductive plate, the bonding material, and the semiconductor chip; and
the first resin sheet cures at a temperature equal to or lower than a temperature at which the sealing resin cures.

4. The semiconductor device according to claim 1, wherein:
the semiconductor module includes a sealing resin sealing the heat dissipation plate, the first resin sheet, the electrically-conductive plate, the bonding material, and the semiconductor chip;
the first resin sheet covers a whole top surface of the heat dissipation plate;
the electrically-conductive plate overlaps a portion of a top surface of the first resin sheet which portion excludes an outer edge of the top surface;
the top surface of the first resin sheet has a region around a contact region in contact with the electrically-conductive plate which region has a groove formed to surround the contact region and extending from the top surface of the first resin sheet to reach inside of the heat dissipation plate; and
the sealing resin is filled inside the groove.

5. The semiconductor device according to claim 1, wherein:
the semiconductor module includes a sealing resin sealing the heat dissipation plate, the first resin sheet, the electrically-conductive plate, the bonding material, and the semiconductor chip;
the first resin sheet covers a whole top surface of the heat dissipation plate except an outer edge of the top surface;
the top surface of the heat dissipation plate has a region around a contact region in contact with the first resin sheet which region has a groove formed to surround the contact region and extending from the top surface of the heat dissipation plate to reach inside of the heat dissipation plate; and
the sealing resin is filled inside the groove.

6. The semiconductor device according to claim 1, wherein:
the semiconductor module includes a sealing resin sealing the heat dissipation plate, the first resin sheet, the electrically-conductive plate, the bonding material, and the semiconductor chip; and
the semiconductor module has a bottom surface as a recessed-projecting surface subjected to roughening.

7. The semiconductor device according to claim 1, wherein the cooler has a top surface as a recessed-projecting surface subjected to roughening.
